(19) United States
(12) Patent Application Publication
(10) Pub. No.: US 2026/0006715 A1
(43) Pub. Date: Jan. 1, 2026

(54) PRINTED CIRCUIT BOARD

(71) Applicant: SAMSUNG ELECTRO-MECHANICS CO., LTD., Suwon-si (KR)

(72) Inventors: Chi Hyeon Jeong, Suwon-si (KR); Myoung Hoon Kim, Suwon-si (KR); Seok Hwan Kim, Suwon-si (KR); Bong Bu Jung, Suwon-si (KR)

(73) Assignee: SAMSUNG ELECTRO-MECHANICS CO., LTD., Suwon-si (KR)

(21) Appl. No.: 19/051,061

(22) Filed: Feb. 11, 2025

(30) Foreign Application Priority Data
Jun. 28, 2024 (KR) 10-2024-0084920

(51) Int. Cl. H05K 1/02; G02B 6/12; H05K 1/03; H05K 1/11

(52) U.S. Cl. CPC H05K 1/0274; G02B 6/12004; H05K 1/0306; H05K 1/115; G02B 2006/12102; G02B 2006/12104; H05K 2201/10121

(57) ABSTRACT

The present disclosure relates to a printed circuit board including: a substrate having a first through-portion; a metal pattern disposed on at least one surface of the substrate and extending onto a wall surface of the first through-portion; a first optical member disposed in the first through-portion; a dielectric layer disposed on the substrate, filling the first through-portion and covering each of the metal pattern and the first optical member, an optical waveguide pattern embedded in the dielectric layer and disposed on the substrate; and a mirror embedded in the dielectric layer and disposed on the first through-portion.

### CROSS-REFERENCE TO RELATED APPLICATION(S)

This application claims the benefit of priority to Korean Patent Application No. 10-2024-0084920 filed on Jun. 28, 2024, in the Korean Intellectual Property Office, the disclosure of which is incorporated herein by reference in its entirety.

### TECHNICAL FIELD

The present disclosure relates to a printed circuit board.

### BACKGROUND

Since traditional organic packages have low costs and are a mature technology, they are reliable, but recently, with the increase in chip speeds, it has become difficult for the traditional organic packages to sufficiently implement transmission speed. In addition, traditional organic packages may have difficulty in sufficiently securing transparency, and there may be limitations in forming optical waveguides.

### SUMMARY

An aspect of the present disclosure is to provide a printed circuit board that may secure sufficient transparency and may easily form an optical waveguide for transmitting an optical signal.

An aspect of the present disclosure is to provide a printed circuit board including a via structure that may perform both electrical signal connection and optical signal connection.

One of the various solutions proposed through the present disclosure is to form a through-portion in a substrate with excellent transparency and flatness, such as a glass substrate, form a metal pattern capable of electrical signal connection on a wall surface of the through-portion, and arrange an optical member capable of optical signal connection in the through-portion, thereby performing interlayer electrical signal and optical signal transmission.

For example, a printed circuit board according to an example embodiment may include: a substrate having a first through-portion; a metal pattern disposed on at least one surface of the substrate and extending onto a wall surface of the first through-portion; a first optical member disposed in the first through-portion; a dielectric layer disposed on the substrate, filling the first through-portion and covering each of the metal pattern and the first optical member; an optical waveguide pattern embedded in the dielectric layer and disposed on the substrate; and a mirror embedded in the dielectric layer and disposed on the first through-portion.

A printed circuit board may include: a glass substrate having a through-portion; first and second wiring patterns respectively disposed on an upper surface and a lower surface of the glass substrate; a via pattern disposed on a wall surface of the through-portion and electrically connected to the first and second wiring patterns, respectively; a dielectric layer disposed on the upper surface and the lower surface of the glass substrate, filling the through-portion and covering the first and second wiring patterns and the via pattern; first and second optical waveguide patterns respectively disposed on an upper side and a lower side of the glass substrate and spaced apart from the glass substrate and respectively embedded in the dielectric layer; and an optical member disposed in the through-portion, embedded in the dielectric layer, and optically connected to the first and second optical waveguide patterns respectively.

One of the various effects of the present disclosure is to provide a printed circuit board that may secure sufficient transparency and may easily form an optical waveguide for transmitting an optical signal.

Another effect of the various effects of the present disclosure is to provide a printed circuit board including a via structure capable of performing both electrical signal connection signal and optical signal connection.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system;

FIG. 2 is a perspective view schematically illustrating an example of an electronic device;

FIG. 3 is a perspective view schematically illustrating an example of a printed circuit board;

FIG. 4 is a cross-sectional perspective view schematically illustrating a cross-section taken along line A-A; of the printed circuit board of FIG. 3;

FIG. 5 is a schematic cross-sectional view taken along line A-A′ the printed circuit board of FIG. 3;

FIG. 6 is a cross-sectional view schematically illustrating a modified example of the printed circuit board of FIG. 5;

FIGS. 7 and 8 are process cross-sectional views schematically illustrating an example of manufacturing the printed circuit board of FIG. 6;

FIG. 9 is a perspective view schematically illustrating another example of a printed circuit board;

FIG. 10 is a cross-sectional perspective view schematically illustrating a cross-section taken along line B-B′ of the printed circuit board of FIG. 9;

FIG. 11 is a schematic cut cross-sectional view taken along line B-B′ of the printed circuit board of FIG. 9;

FIG. 12 is a cross-sectional view schematically illustrating a modified example of the printed circuit board of FIG. 11; and

FIGS. 13 and 14 are process cross-sectional views schematically illustrating an example of manufacturing the printed circuit board of FIG. 12.

### DETAILED DESCRIPTION

Hereinafter, the present disclosure will be described with reference to the accompanying drawings. In the drawings, the shape and size of the elements may be exaggerated or reduced for clearer description.

### Electronic Device

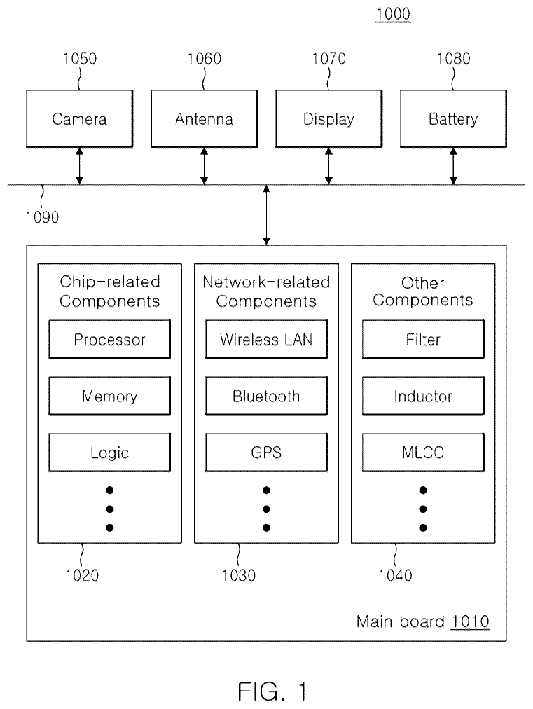

FIG. 1 is a block diagram schematically illustrating an example of an electronic device system.

Referring to FIG. 1, an electronic device 1000 accommodates a main board 1010 therein. Chip-related components 1020, network-related components 1030, other components 1040, and the like, are physically and/or electrically connected to the main board 1010. These components are also coupled to other electronic components to be described below to form various signal lines 1090.

The chip-related components 1020 may include a memory chip such as a volatile memory (e.g., a DRAM), a non-volatile memory (e.g., a ROM), a flash memory, or the like; an application processor chip such as a central processor (e.g., a CPU), a graphics processor (e.g., a GPU), a digital signal processor, a cryptographic processor, a microprocessor, a microcontroller, or the like; and a logic chip such as an analog-to-digital (ADC) converter, an application-specific IC (ASIC), or the like. However, the chip-related components 1020 are not limited thereto, and may also include other types of chip-related electronic components. Furthermore, the chip-related components 1020 may be coupled to each other. The chip-related component 1020 may have the form of a package including the above-described chip or electronic component.

The network-related components 1030 may include wireless fidelity (Wi-Fi) (such as IEEE 802.11 family), worldwide interoperability for microwave access (WiMAX) (such as IEEE 802.16 family), IEEE 802.20, long term evolution (LTE), evolution data only (Ev-DO), HSPA+, HSDPA+, HSUPA+, EDGE, GSM, GPS, GPRS, CDMA, TDMA, DECT, Bluetooth®, 3G, 4G, and 5G protocols, and any other wireless and wired standards or protocols specified thereafter. However, the network-related components 1030 are not limited thereto, and may also include any of a number of other wireless or wired standards or protocols. Furthermore, the network-related components 1030 may be coupled to the chip-related components 1020.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components are not limited thereto, and may also include passive components in the form of chip components used for various other purposes. In addition, other components 1040 may be coupled to each other, together with the chip-related components 1020 and/or the network-related components 1030.

Depending on a type of electronic device 1000, the electronic device 1000 may include other electronic components that may or may not be physically and/or electrically connected to main board 1010. These other electronic components may include, for example, a camera module 1050, an antenna module 1060, a display 1070, and a battery 1080. However, these other electronic components are not limited thereto, but may also include an audio codec, a video codec, a power amplifier, a compass, an accelerometer, a gyroscope, a speaker, a mass storage device (e.g., a hard disk drive), a compact disk (CD), a digital versatile disk (DVD), or the like. In addition thereto, other electronic components used for various purposes depending on a type of electronic device 1000 may be included.

The electronic device 1000 may be a smartphone, a personal digital assistant, a digital video camera, a digital still camera, a network system, a computer, a monitor, a tablet PC, a laptop PC, a netbook PC, a television, a video game machine, a smartwatch, an automotive component. However, the electronic device 1000 is not limited thereto, and may be any other electronic device that processes data in addition thereto.

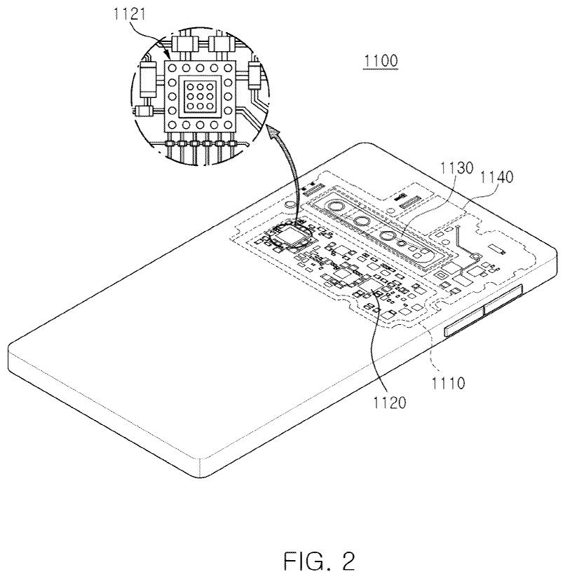

FIG. 2 is a perspective view schematically illustrating an example of an electronic device.

Referring to FIG. 2, an electronic device may be, for example, a smartphone 1100. A mother board 1110 may be accommodated in the smartphone 1100, and various components 1120 may be physically and/or electrically connected to the mother board 1110. Furthermore, other components that may or may not be physically and/or electrically connected to the mother board 1110, such as a camera module 1130 and/or a speaker 1140, may be accommodated in the smartphone 1100. Some of the components 1120 may be the chip-related components described above, for example, the component package 1121, but the present disclosure is not limited thereto. The component package 1121 may have the form of a printed circuit board in which an electronic component including an active component and/or a passive component is mounted on a surface. Alternatively, the component package 1121 may have the form of a printed circuit board in which an active component and/or a passive component are embedded. On the other hand, the electronic device is not necessarily limited to the smartphone 1100, and may be other electronic devices as described above.

### Printed Circuit Board

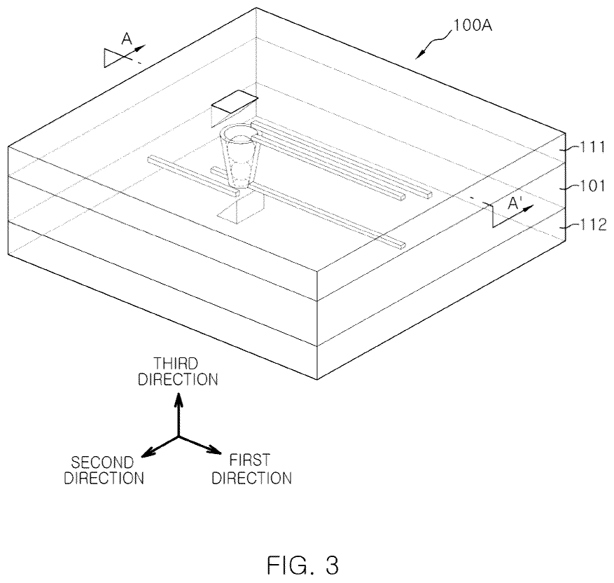

FIG. 3 is a perspective view schematically illustrating an example of a printed circuit board.

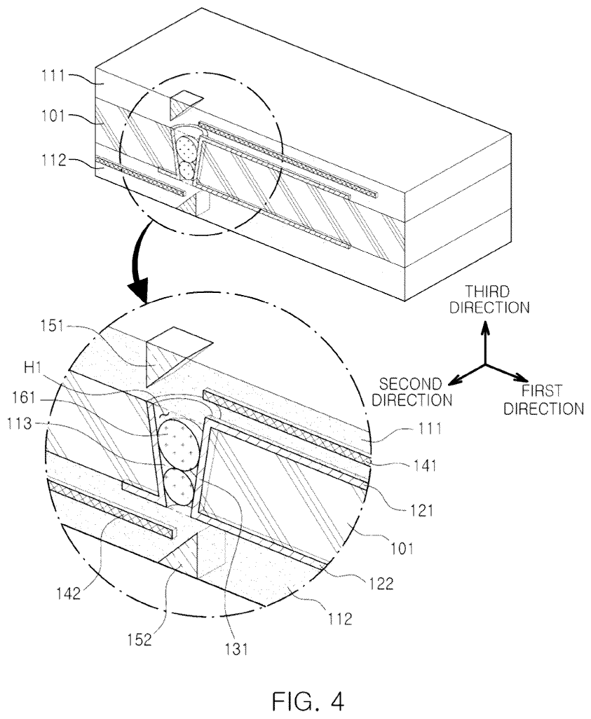

FIG. 4 is a cross-sectional perspective view schematically illustrating a cross-section taken along line A-A; of the printed circuit board of FIG. 3.

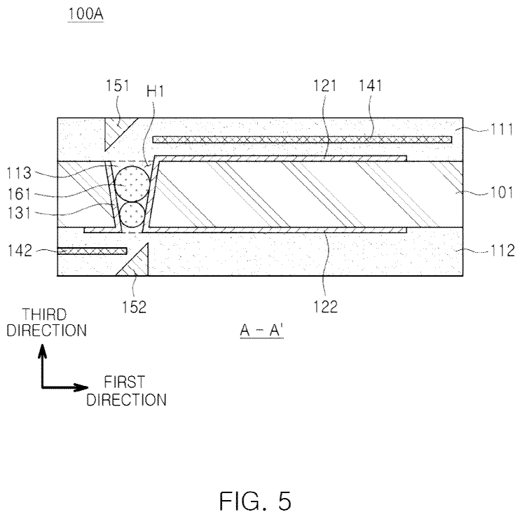

FIG. 5 is a schematic cut cross-sectional view taken along line A-A′ the printed circuit board of FIG. 3.

Referring to the drawings, a printed circuit board 100A according to an example embodiment may include a substrate 101 having a through-portion H1, metal patterns 121, 122 and 131 disposed on at least one surface of the substrate 101 and extending onto a wall surface of the through-portion H1, an optical member 161 disposed in the through-portion H1, dielectric layers 111, 112 and 113 disposed on the substrate 101, filling the through-portion H1 and covering each of the metal patterns 121, 122 and 131 and the optical member 161, optical waveguide patterns 141 and 142 embedded in the dielectric layers 111, 112 and 113 and disposed on the substrate 101, and mirrors 151 and 152 embedded in the dielectric layers 111, 112 and 113 and disposed on the through-portion H1.

In this manner, in the printed circuit board 100A according to an example embodiment, the metal patterns 121, 122 and 131 may be disposed to extend on the wall surface of the through-portion H1, and thus, not only electrical signal transmission in a first and/or second direction, but also interlayer electrical signal transmission in a third direction may be performed. Additionally, an optical member 161 may be disposed in the through-portion H1. In this case, optical waveguide patterns 141 and 142 disposed on different levels based on the third direction may be optically connected to the optical member 161 through the mirrors 151 and 152 to enable transmission of an optical signal therethrough, and thus, not only optical signal transmission in the first and/or second direction, but also optical signal transmission in the third direction may be performed. Thus, two types of signal transmission, for example, optical/electrical signals, may be performed through a single via structure. The common use of the via may be more advantageous in securing design space. Accordingly, more signal line designs may be possible. Additionally, the size of a product may be reduced.

As used herein, the term “optically connected” refers to an arrangement of one or more optical components that enables transmission of an optical signal through the one or more optical components without substantial distortion or attenuation.

The substrate 101 may include a glass substrate. The glass substrate has superior warpage characteristics and flatness than a core layer including an organic material, which may be more advantageous in reducing a line/space of a trace formed thereon. Additionally, the glass substrate has superior transparency, and therefore may be more advantageous in optical signal transmission. For example, the amount of data transmission and the speed may be improved. Accordingly, the glass substrate may be easily applied to silicon photonics technology. Silicon photonics may increase the amount of data transmission and the speed by partially changing existing electrical signals into optical signals.

The metal patterns 121, 122 and 131 may include first and second wiring patterns 121 and 122 respectively disposed on an upper surface and a lower surface of the substrate 101, and a via pattern 131 disposed on the wall surface of the through-portion H1 and electrically connected to the first and second wiring patterns 121 and 122, respectively. For example, the first and second wiring patterns 121 and 122 including traces for signal transmission may be disposed on both surfaces of the substrate 101, respectively, and the via pattern 131 electrically connecting the first and second wiring patterns 121 and 122 may be disposed on the wall surface of the through-portion H1. Accordingly, a structure more advantageous for interlayer electrical signal transmission may be provided.

The dielectric layers 111, 112 and 113 may include first and second dielectric layers 111 and 112 respectively disposed on the upper surface and the lower surface of the substrate 101 and covering the first and second wiring patterns 121 and 122, respectively, and a third dielectric layer 113 filling the first through-portion H1 and covering the optical member 161. In this case, the optical waveguide patterns 141 and 142 may include first and second optical waveguide patterns 141 and 142 respectively embedded in the first and second dielectric layers 111 and 112 on an upper side and a lower side of the substrate 101. Additionally, the optical member 161 may be embedded in the third dielectric layer 113 in the through-portion H1. Additionally, the mirrors 151 and 152 may include first and second mirrors 151 and 152 embedded in the first and second dielectric layers 111 and 112, respectively, on an upper side and a lower side of the through-portion H1. The first and second mirrors 151 and 152 may optically connect each of the first and second optical waveguide patterns 141 and 142 respectively to the optical member 161 to enable transmission of an optical signal therethrough. Accordingly, a structure more advantageous for interlayer optical signal transmission may be provided.

Each of the first to third dielectric layers 111, 112 and 113 and the first and second optical waveguide patterns 141 and 142 may include a transparent dielectric. This case may be more advantageous for optical signal transmission. Here, the transparent dielectric may have a transmittance of approximately 90% or more by measuring and evaluating the transmittance in a visible light range (e.g., wavelength ranging from 400 nm to 700 nm). In this case, the first and second optical waveguide patterns 141 and 142 may have a refractive index greater than that of the first and second dielectric layers 111 and 112, respectively. Accordingly, the first and second dielectric layers 111 and 112 may effectively prevent the optical signals received through the first and second optical waveguide patterns 141 and 142 from being transmitted to the outside or leaked into the dielectric layers. The first and second optical waveguide patterns 141 and 142 may be provided in plural, respectively, as needed.

The first mirror 151 may have a surface inclined in a direction facing an upper end of the through-portion H1 and one end of the first optical waveguide pattern 141. Additionally, the second mirror 152 may have a surface inclined in a direction facing a lower end of the through-portion H1 and one end of the second optical waveguide pattern 142. Here, the inclined surface may have an acute angle with respect to the first and/or third directions on a cross-section. Additionally, each of the first and second mirrors 151 and 152 may include a metal. Since the first and second mirrors 151 and 152 include a metal and have inclined surfaces, this may be more advantageous for optically connecting the first and second optical waveguide patterns 141 and 142 to the optical member 161 to enable transmission of optical signals therethrough, respectively. The first and second mirrors 151 and 152 may have an approximately triangular or a prism shape on the cross-section, but the present disclosure is not limited thereto.

The optical member 161 may include one or more ball lenses. The one or more ball lenses may be one or two, but the present disclosure is not limited thereto. When the one or more ball lenses are provided in plural, a plurality of ball lenses may be stacked in a stacking direction, for example, in a third direction. The plurality of ball lenses may have the same size, but are not limited thereto, and may be adjusted according to the size of the through-portion H1. For example, the plurality of ball lenses may form a tapered shape in which a width of an upper end thereof is wider than that of a lower end thereof on the cross-section of the through-portion H1, in which case, a ball lens disposed on the upper side of the through-portion H1, among the plurality of ball lenses, may have a wider width on the cross-section than a ball lens disposed on the lower side of the through-portion H1. For example, the diameter of the ball lens disposed on the upper side of the through-portion H1 may be larger than the ball lens disposed on the lower side of the through-portion H1. For example, a size of the ball lens disposed on the upper side of the through-portion H1 may be larger than the ball lens disposed on the lower side of the through-portion H1. In this case, the plurality of ball lenses may be stably inserted into the through-portion H1 and may be stably stacked in the stacking direction, for example, in the third direction.

Hereinafter, components of a printed circuit board 100A according to an example embodiment will be described in more detail with reference to the drawings.

The substrate 101 may be a core layer of a printed circuit board 100A. The substrate 101 may include an organic insulating material or an inorganic insulating material. The organic insulating material may include a thermosetting resin such as an epoxy resin, a thermoplastic resin such as a polyimide, or an inorganic filler, an organic filler, and/or glass fiber (Glass Fiber, Glass Cloth or Glass Fabric) together with the resin. The inorganic insulating material may include glass, silicon, and ceramic. For example, the substrate 101 may include a glass substrate, a silicon substrate, and a ceramic substrate, and may include, preferably, a glass substrate. The glass substrate may include glass, which is an amorphous solid. The glass may include, for example, pure silicon dioxide (about 100% SiO₂), soda lime glass, borosilicate glass, and alumino-silicate glass. However, the present disclosure is not limited thereto, and alternative glass materials, such as fluorine glass, phosphate glass, chalcogen glass, or the like, may also be used as materials. Additionally, other additives may be further included to form a glass having specific physical properties. The additives may include not only calcium carbonate (e.g., lime) and sodium carbonate (e.g., soda), but also magnesium, calcium, manganese, aluminum, lead, boron, iron, chromium, potassium, sulfur, and antimony, and carbonates and/or oxides of these elements and other elements. The glass substrate may be distinguished from the organic insulating material including the above-described glass fiber, such as Copper Clad Laminate (CCL), Prepreg (PPG), or the like. For example, plate glass may be included.

The first to third dielectric layers 111, 112 and 113 may protect the first and second optical waveguide patterns 141 and 142 and the optical member 161. The first to third dielectric layers 111, 112 and 113 may include a transparent dielectric. The transparent dielectric may be, for example, a polymer, but is not limited thereto, and may include other materials capable of transmitting optical signals. For example, the transparent dielectric may include silica, glass, lithium niobate (LiNbO₃), lithium tantalate (LiTaO₃), and a III-V group semiconductor compound. The first to third dielectric layers 111, 112 and 113 may include the same material, and boundaries thereof may be ambiguous. However, the present disclosure is not limited thereto, and the first to third dielectric layers 111, 112 and 113 may include different materials, and boundaries thereof may be identified.

The first and second wiring patterns 121 and 122 and the via pattern 131 are conductive patterns including a material having relatively high electrical conductivity and may be used to transmit electrical signals. Each of the first and second wiring patterns 121 and 122 and the via pattern 131 may include a metal. The metal may include copper (Cu), aluminum (Al), silver (Ag), tin (Sn), gold (Au), nickel (Ni), lead (Pb), titanium (Ti), and/or alloys thereof. The metal may include, preferably, copper (Cu), but is not limited thereto. The first and second wiring patterns 121 and 122 and the via pattern 131 may include a signal pattern, and may further include a power pattern and/or a ground pattern as needed. The patterns may have a shape such as a line, a pad, or a plate. Each of the first and second wiring patterns 121 and 122 and the via pattern 131 may include a seed layer and a plating layer. The seed layer may be formed by electroless plating (e.g., chemical copper), and may be formed in a sputtering process if necessary. Alternatively, the seed layer may be formed through both the electroless plating and the sputtering process. The plating layer may be formed by electrolytic plating (e.g., electrolytic copper). The first and second wiring patterns 121 and 122 may be protruding patterns protruding onto the substrate 101, but are not limited thereto, and may be applied as embedded patterns embedded in the substrate 101 if necessary.

The first and second optical waveguide patterns 141 and 142 are patterns capable of transmitting optical power and may be used for transmitting optical signals. Each of the first and second optical waveguide patterns 141 and 142 may include a transparent dielectric. The transparent dielectric may be, for example, a polymer, but is not limited thereto, and may include other materials capable of transmitting optical power. For example, the transparent dielectric may include silica, glass, lithium niobate (LiNbO₃), lithium tantalate (LiTaO₃), and a III-V group semiconductor compound. The first and second optical waveguide patterns 141 and 142 may have shapes such as a line or a plate.

The optical member 161 may include one or more ball lenses. The one or more ball lenses may be inserted into the through-portion H1 to transmit incident light or refract the light as required. When the one or more ball lenses are provided in plural, a plurality of ball lenses may be stacked in the stacking direction, for example, the third direction, for easier transmission of optical signals. When the one or more ball lenses are provided in plural, the plurality of ball lenses may have the same size or different sizes. The one or more ball lenses may include silica and glass, but the present disclosure is not limited thereto, and any material that may be used for transmitting an optical signal may be applied thereto. Each of the one or more ball lenses may have a spherical shape, and the spherical shape may include not only a perfect spherical shape but also an approximately spherical shape or an elliptical sphere. Each of the one or more ball lenses may be in contact with the via pattern 131 disposed on the wall surface of the through-portion H1, but is not limited thereto.

The first and second mirrors 151 and 152 may cause a change in an optical path of an optical signal incident thereon. For example, each of the first and second mirrors 151 and 152 may be disposed between the first and second optical waveguide patterns 141 and 142 and the one or more ball lenses, respectively, and may direct an optical signal from the first and/or second direction to the third direction, or may direct an optical signal from the third direction to the first and/or second direction. Each of the first and second mirrors 151 and 152 may include a metal. The metal may include copper (Cu), aluminum (Al), silver (Ag), tin (Sn), gold (Au), nickel (Ni), lead (Pb), titanium (Ti), and/or alloys thereof. If necessary, a material having a different reflective property other than the metal may be used as the material of the first and second mirrors 151 and 152. The first and second mirrors 151 and 152 may be formed in a deposition method such as sputtering, in which case each of the first and second mirrors 151 and 152 may include a sputtering layer. However, the present disclosure is not limited thereto, and the first and second mirrors 151 and 152 may be formed in a general plating process if necessary. In this case, each of the first and second mirrors 151 and 152 may include an electroless plating layer and/or an electrolytic plating layer.

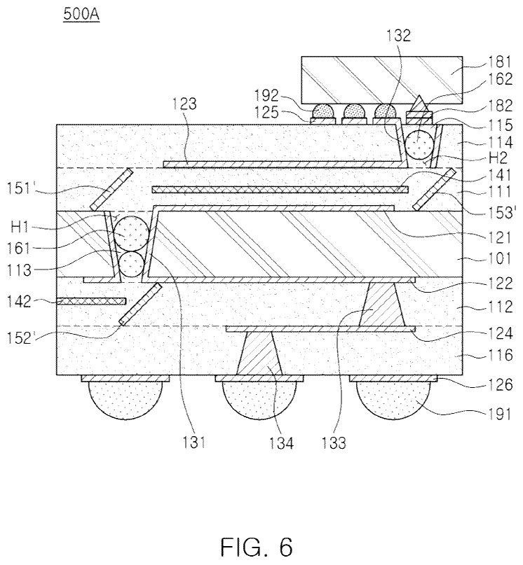

FIG. 6 is a cross-sectional view schematically illustrating a modified example of the printed circuit board of FIG. 5.

Referring to FIG. 6, a printed circuit board 500A according to a modified example embodiment may further include a photonic Integrated Circuit (PIC) 181 disposed on an upper side of the first dielectric layer 111, and a third mirror 153′ embedded in the first dielectric layer 111 on a lower side of the PIC 181 and configured to optically connect the first optical waveguide pattern 141 to the PIC 181 to enable transmission of optical signals therethrough, in the printed circuit board 100A described above. If necessary, the printed circuit board 500A may further include one or more of the following structures: a fourth dielectric layer 114 disposed between the first dielectric layer 111 and the PIC 181 and having a second through-portion H2 between the PIC 181 and the third mirror 153′, a third wiring pattern 123 disposed between the first and fourth dielectric layers 111 and 114, a second via pattern 132 disposed on a wall surface of the second through-portion H2 and electrically connected to the third wiring pattern 123, a second optical member 162 disposed in the second through-portion H2, a fifth dielectric layer 115 filling the second through-portion H2 and covering the second optical member 162, a sixth dielectric layer 116 disposed on a lower side of the second dielectric layer 112, a fourth wiring pattern 124 disposed between the second and sixth dielectric layers 112 and 116, a third via pattern 133 penetrating through the second dielectric layer 112 and electrically connecting the second and fourth wiring patterns 122 and 124, a fourth via pattern 134 penetrating through the sixth dielectric layer 116 and electrically connecting the fourth and sixth wiring patterns 124 and 126, a fifth wiring pattern 125 disposed on an upper surface of the fourth dielectric layer 114, a sixth wiring pattern 126 disposed on a lower surface of the sixth dielectric layer 116, an electrical connection metal 191 connected to the sixth wiring pattern 126, and/or a connecting member 192 connecting the PIC 181 to the fifth wiring pattern 125. For example, the printed circuit board 500A according to the modified example embodiment may be a package structure including the structure of the printed circuit board 100A described above. For example, the printed circuit board 500A may be a package structure in which the PIC 181 is mounted on a surface thereof.

Each of first to third mirrors 151′, 152′ and 153′ may have a plate shape having a predetermined thickness along the inclined surface described above. The first to third mirrors 151′, 152′ and 153′ may be formed by metal deposition. However, the present disclosure is not limited thereto, and the first to third mirrors 151′, 152′ and 153′ may be formed by a deposition process or the like, using materials having other reflective properties other than the metal.

Hereinafter, components of the printed circuit board 500A according to a modified example embodiment will be described in more detail with reference to the drawings.

The fourth and sixth dielectric layers 114 and 116 may include a general build-up polymer. For example, the fourth and sixth dielectric layers 114 and 116 may include a thermosetting resin such as an epoxy resin, a thermoplastic resin such as a polyimide, or a polymer including an inorganic filler, an organic filler, and/or glass fiber together with the resin. However, the present disclosure is not limited thereto, and the fourth and sixth dielectric layers 114 and 116 may also include the transparent dielectric described above, similar to the first and second dielectric layers 111 and 112. For example, the fourth and sixth dielectric layers 114 and 116 may include the same material, and boundaries thereof may be ambiguous. However, the present disclosure is not limited thereto, and the fourth and sixth dielectric layers 114 and 116 may include different materials, and boundaries thereof may be identified. The fifth dielectric layer 115 may protect the second optical member 162. The fifth dielectric layer 115 may include the transparent dielectric described above, similar to the third dielectric layer 113.

The third to sixth wiring patterns 123, 124, 125 and 126 and the second to fourth via patterns 132, 133 and 134 are conductive patterns including a material having relatively high electrical conductivity and may be used for transmitting electrical signals. In addition, the contents of the first and second wiring patterns 121 and 122 and the first via pattern 131 described above may be substantially identically applied to the third to sixth wiring patterns 123, 124, 125 and 126 and the second via pattern 132. Each of the third and fourth via patterns 133 and 134 may have a form in which a via hole in which a width of an upper end thereof is narrower than a width of a lower end thereof on a cross-section is filled with the metal described above. The third and fourth via patterns 133 and 134 may include signal vias, but may also further include power vias and/or ground vias. Each of the third and fourth via patterns 133 and 134 may include a seed layer and a plating layer. The seed layer may be formed by electroless plating (e.g., chemical copper), and may be formed by a sputtering process, if necessary. Alternatively, the seed layer may be formed using both the electroless plating and the sputtering process. A plating layer may be formed by electrolytic plating (e.g., electrolytic copper).

The second optical member 162 may include one or more second ball lenses. The one or more second ball lenses may be inserted into the second through-portion H2 and may transmit incident light or refract the light as needed. For example, the light incident through the first optical waveguide pattern 141 and the third mirror 153′ may be transmitted to the PIC 181, or vice versa. In addition, the contents described in the one or more first ball lenses described above may be substantially identically applied to the one or more second ball lenses.

The third mirror 153′ may cause a change in an optical path of an optical signal incident thereon. For example, the third mirror 153′ may be disposed between the first optical waveguide pattern 141 and the one or more second ball lenses and may direct an optical signal from the first and/or second direction to the third direction, or may direct an optical signal from the third direction to the first and/or second directions. The third mirror 153′ may have a surface inclined in a direction facing a lower end of the second through-portion H2 and the other end of the first optical waveguide pattern 141. Here, the inclined surface may have an acute angle with respect to the first and/or third directions on the cross-section. Additionally, the contents described in the first and second mirrors 151 and 152 described above may be substantially applied to the third mirror 153′.

The PIC 181 may convert an electrical signal into an optical signal, and/or may convert an optical signal into an electrical signal. A light source, such as, e.g., a laser 182 may be disposed between the PIC 181 and the second optical member 162. The PIC 181 may be connected to the fifth wiring pattern 125 through the connecting member 192. The connecting member 192 may be formed of a conductive material, such as solder, or the like, but this is only an example and the material is not particularly limited thereto.

The electrical connection metal 191 may connect a printed circuit board 500A to another substrate, or the like. The electrical connection metal 191 may be connected to the fifth wiring pattern 125. The electrical connection metal 191 may also be formed of a conductive material, such as solder, or the like, but this is only an example and the material is not particularly limited thereto. The electrical connection metal 191 may be a land, a ball, a pin, or the like, respectively. The electrical connection metal 191 may be formed of multiple layers or a single layer. When the electrical connection metal 191 is formed of multiple layers, the electrical connection metal 191 may include a copper pillar and a solder formed on the copper pillar, and when the electrical connection metal 191 is formed of a single layer, the electrical connection metal 191 may include tin-silver solder or copper, but the present disclosure is not limited thereto.

Other contents may be substantially the same as those described in the printed circuit board 100A according to the above-described example embodiment, and redundant descriptions thereof will be omitted.

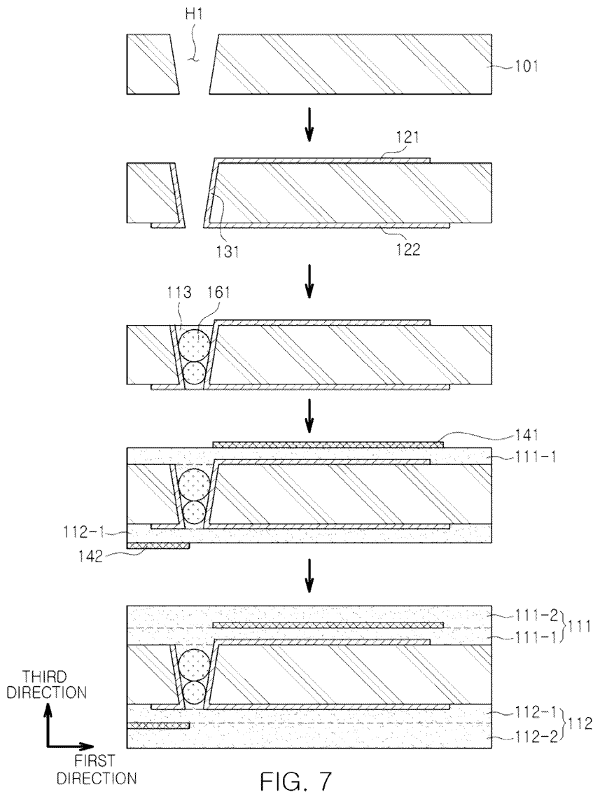

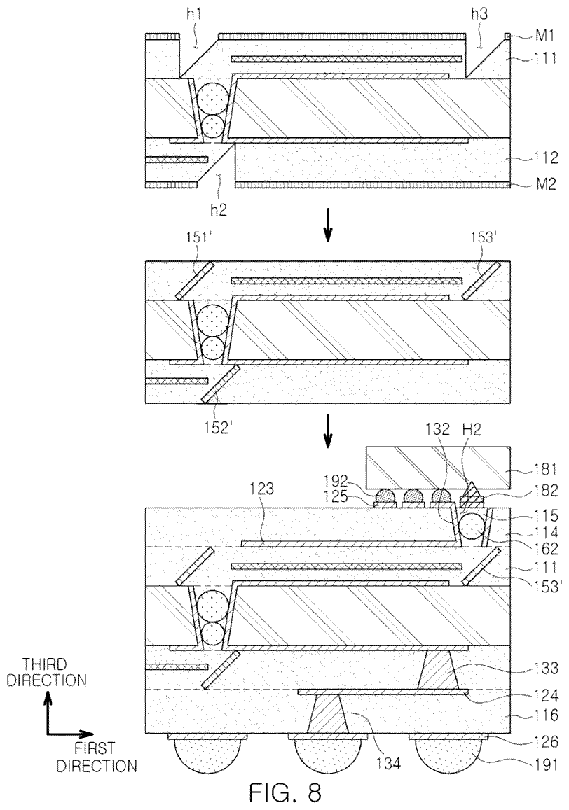

FIG. 7 and FIG. 8 are process cross-sectional views schematically illustrating an example of manufacturing the printed circuit board of FIG. 6.

Referring to FIG. 7, first, a substrate 101 may be prepared, and a first through-portion H1 may be formed on the substrate 101. The first through-portion H1 may be formed in a chemical method or a mechanical method, depending on the material of the substrate 101. For example, etching, blasting, laser, plasma, or the like, may be used as a formation method. Next, first and second wiring patterns 121 and 122 and a first via pattern 131 may be formed on the substrate 101 and the first through-portion H1. The first and second wiring patterns 121 and 122 and the first via pattern 131 may be formed through a plating process, respectively. Next, a first optical member 161, for example, one or more first ball lenses, may be inserted into the first through-portion H1. In the case in which the one or more first ball lenses are provided in plural, a plurality of first ball lenses may be sequentially inserted in the third direction and may be stacked in the first through-portion H1. Then, the first through-portion H1 may be filled with a third dielectric layer 113. For example, a plugging process may be performed using a transparent dielectric as a material. Next, first-first and second-first dielectric layers 111-1 and 112-1 may be formed on an upper surface and a lower surface of the substrate 101, respectively. For example, a stacking process or a coating process may be performed using a transparent dielectric as a material. Then, first and second optical waveguide patterns 141 and 142 may be formed on an upper surface of the first-first dielectric layer 111-1 and a lower surface of the second-first dielectric layer 112-1, respectively. The first and second optical waveguide patterns 141 and 142 may be formed, for example, by patterning a photosensitive transparent dielectric in a photolithography process. Next, first-second and second-second dielectric layers 111-2 and 112-2 covering the first and second optical waveguide patterns 141 and 142 may be formed on the upper surface of the first-first dielectric layer 111-1 and the lower surface of the second-first dielectric layer 112-1, respectively. For example, a stacking process or a coating process may be performed using a transparent dielectric as a material. Then, the first and second dielectric layers 111 and 112 may be formed.

Referring to FIG. 8, next, first to third openings h1, h2 and h3 having inclined wall surfaces may be formed in the first and second dielectric layers 111 and 112 using first and second masks M1 and M2. The first to third openings h1, h2 and h3 may be formed by laser ablation, or the like. Next, first to third mirrors 151′, 152′ and 153′ in a form of a plate with a predetermined thickness may be formed only on the inclined surfaces of each of the first to third openings h1, h2 and h3 through metal deposition, and then, a remaining space of each of the first to third openings h1, h2 and h3 may be filled with a dielectric material using a plugging process, or the like. If necessary, shapes of the first to third openings h1, h2 and h3 may be partially adjusted and then filled with a metal material to form a mirror having the shape illustrated in FIG. 5. Then, the first and second masks M1 and M2 may be removed. Next, third and fourth wiring patterns 123 and 124 and a third via pattern 133 may be formed on the first and second dielectric layers 111 and 112 through a via hole processing process, a plating process, and the like. Additionally, the fourth and sixth dielectric layers 114 and 116 may be formed on the first and second dielectric layers 111 and 112, respectively, through a stacking process or a coating process. Additionally, a second through-portion H2, fifth and sixth wiring patterns 125 and 126, and second and fourth via patterns 132 and 134 may be formed in the fourth and sixth dielectric layers 114 and 116 through via a hole processing process, a through-portion processing process, a plating process, and the like. Additionally, a second optical member 162, for example, one or more second ball lenses, may be inserted into the second through-portion H2. Additionally, the fifth dielectric layer 115 may be filled in the remaining space of the second through-portion H2 through a plugging process. Additionally, the PIC 181 may be mounted using the connecting member 192, and the laser 182 may be disposed as needed. Additionally, an electrical connection metal 191 may be formed through a solder ball attachment and a reflow process. A structure of the printed circuit board 500A according to the above-described modified example embodiment may be manufactured through a series of processes.

Other descriptions may be substantially the same as those described in the printed circuit board 100A according to the above-described example embodiment, the printed circuit board 500A according to the modified example embodiment, and therefore, redundant descriptions thereof will be omitted.

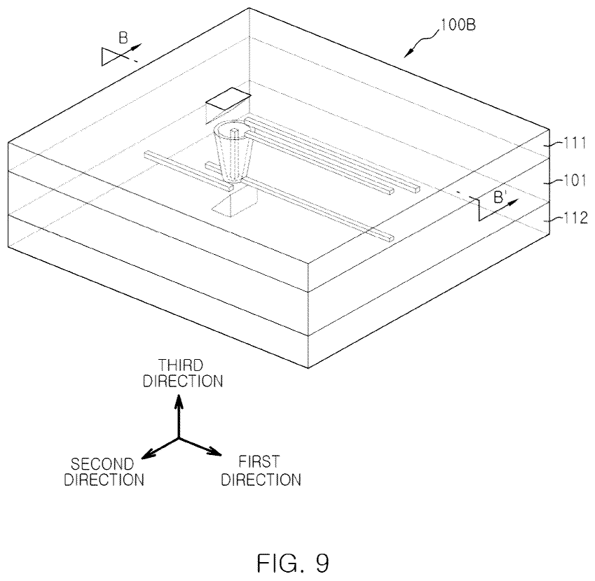

FIG. 9 is a perspective view schematically illustrating another example of a printed circuit board.

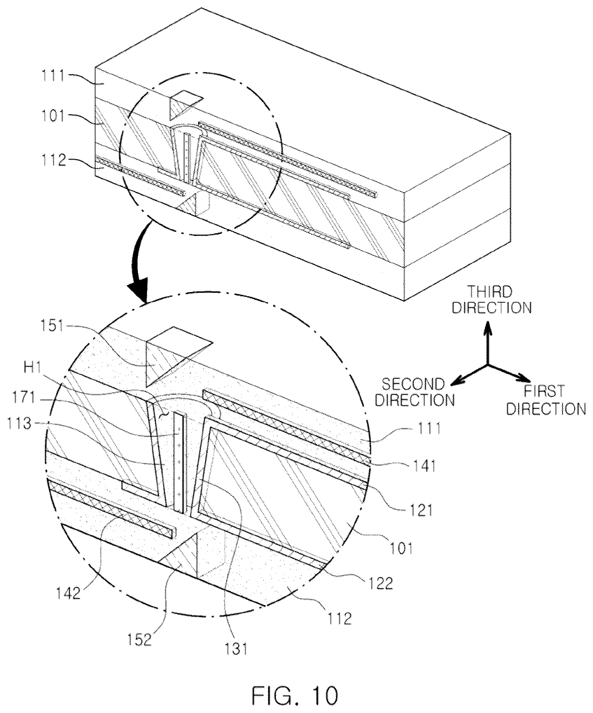

FIG. 10 is a cross-sectional perspective view schematically illustrating a cross-section taken along line B-B′ of the printed circuit board of FIG. 9.

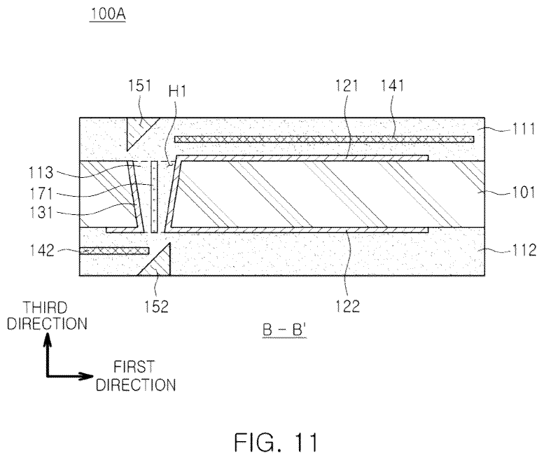

FIG. 11 is a schematic cut cross-sectional view taken along line B-B′ of the printed circuit board of FIG. 9.

Referring to the drawings, a printed circuit board 100B according to another example embodiment may have an optical member 171 having a different form instead of the optical member 161 applied thereto, in the printed circuit board 100A described above. For example, the optical member 171 may include an optical waveguide via pattern penetrating through the third dielectric layer 113 in the stacking direction in the through-portion H1. For example, in another example embodiment, an optical waveguide via pattern may be applied to the via structure instead of a ball lens for optical signal transmission.

Each of the third dielectric layer 113 and the optical member 171, for example, the optical waveguide via pattern, may include a transparent dielectric. In this case, this may be more advantageous for optical signal transmission. Here, a transparent dielectric may have a transmittance of approximately 90% or more, by measuring and evaluating the transmittance in a visible light range (400 nm to 700 nm). In this case, the optical waveguide via pattern may have a higher refractive index than the third dielectric layer 113. Accordingly, the third dielectric layer 113 may effectively prevent an optical signal received through the optical waveguide via pattern from being transmitted to the outside. The optical waveguide via pattern may be provided in plural, as needed.

Hereinafter, components of a printed circuit board 100B according to another example embodiment will be described in more detail with reference to the drawings.

The optical member 171 may include an optical waveguide via pattern. The optical waveguide via pattern is a pattern capable of transporting optical power and may be used for transmitting an optical signal. The optical waveguide via pattern may include a transparent dielectric. The transparent dielectric may be, for example, a polymer, but the present disclosure is not limited thereto, and may include other materials capable of transporting optical power. For example, the transparent dielectric may include silica, glass, lithium niobate (LiNbO₃), lithium tantalate (LiTaO₃), and a III-V group semiconductor compound. The optical waveguide via pattern may be generally linear or planar in shape.

Other descriptions may be substantially the same as those described in the printed circuit board 100A according to the above-described example embodiment, the printed circuit board 500A according to the modified example embodiment, and the like, and thus, redundant descriptions thereof will be omitted.

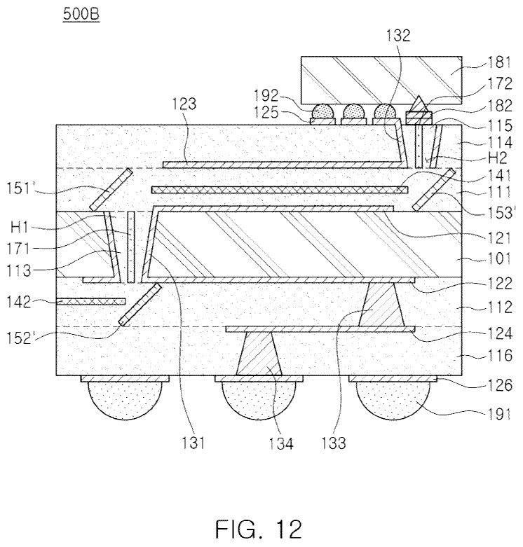

FIG. 12 is a cross-sectional view schematically illustrating a modified example of the printed circuit board of FIG. 11.

Referring to FIG. 12, a printed circuit board 500B according to a modified example embodiment may have first and second optical members 171 and 172 having different shapes instead of the first and second optical members 161 and 162 applied thereto, in the printed circuit board 500A described above. For example, the first optical member 171 may include a first optical waveguide via pattern penetrating through the third dielectric layer 113 in the stacking direction in the first through-portion H1. Additionally, the second optical member 172 may include a second optical waveguide via pattern penetrating through the fifth dielectric layer 115 in the stacking direction in the second through-portion H2. For example, in a modified example, an optical waveguide via pattern, rather than a ball lens, may be applied to the via structure, for optical signal transmission.

Each of the fifth dielectric layer 115 and the second optical member 172, for example, the second optical waveguide via pattern, may include a transparent dielectric.

In this case, this may be more advantageous for optical signal transmission. Here, the transparent dielectric may have a transmittance of approximately 90% or more, by measuring and evaluating the transmittance in a visible light range (e.g., in a range from 400 nm to 700 nm). In this case, the second optical waveguide via pattern may have a higher refractive index than the fifth dielectric layer 115. Accordingly, the fifth dielectric layer 115 may effectively prevent the optical signal received through the second optical waveguide via pattern from being transmitted to the outside. The second optical waveguide via pattern may be provided in plural, as needed.

Hereinafter, components of a printed circuit board 500B according to a modified example embodiment will be described in more detail with reference to the drawings.

The first and second optical members 171 and 172 may include first and second optical waveguide via patterns, respectively. Each of the first and second optical waveguide via patterns is a pattern capable of transporting optical power, and may be used for transmitting optical signals. The first and second optical waveguide via patterns may include a transparent dielectric, respectively. The transparent dielectric may be, for example, a polymer, but is not limited thereto, and may include other materials capable of transporting optical power. For example, the transparent dielectric may include silica, glass, lithium niobate (LiNbO₃), lithium tantalate (LiTaO₃), and a III-V group semiconductor compound. The first and second optical waveguide via patterns may have a generally linear or planar shape, respectively.

Other descriptions may be substantially the same as those described in the printed circuit board 100A according to the above-described example embodiment, the printed circuit board 500A according to the modified example embodiment, the printed circuit board 100B according to another example, and the like, and therefore, redundant descriptions thereof will be omitted.

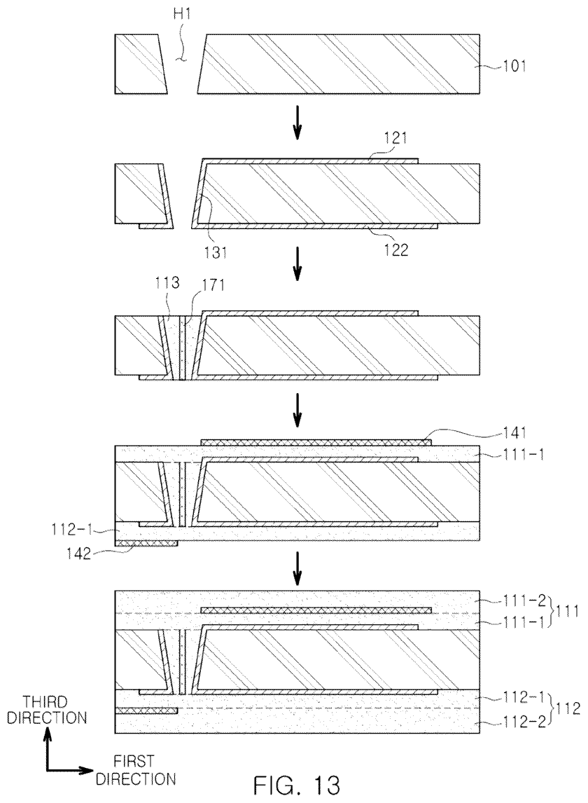

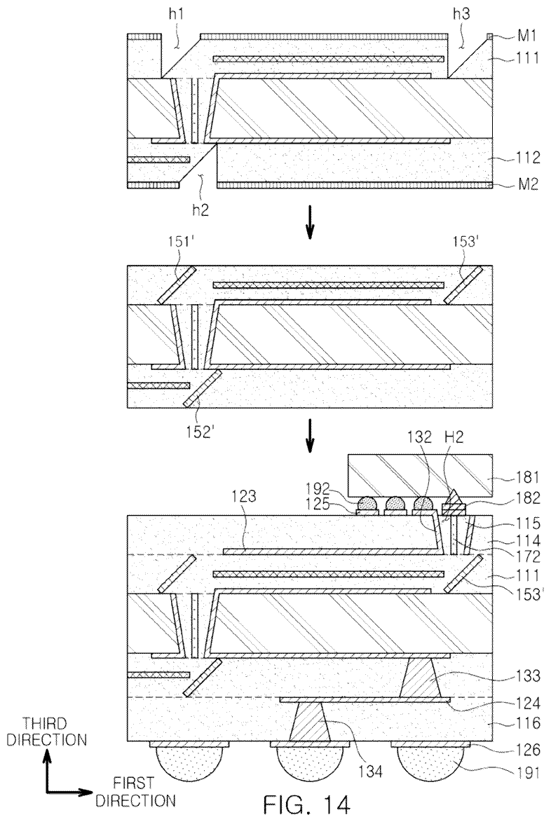

FIG. 13 and FIG. 14 are process cross-sectional views schematically illustrating an example of manufacturing the printed circuit board of FIG. 12.

Referring to FIG. 13, first, a substrate 101 may be prepared, and a first through-portion H1 may be formed on the substrate 101. The first through-portion H1 may be formed in a chemical method or a mechanical method, depending on the material of the substrate 101. For example, etching, blasting, laser, plasma, or the like, may be used as a formation method. Next, first and second wiring patterns 121 and 122 and a first via pattern 131 may be formed on the substrate 101 and the first through-portion H1. The first and second wiring patterns 121 and 122 and the first via pattern 131 may be formed through a plating process, respectively. Next, the first through-portion H1 may be filled with a third dielectric layer 113. For example, a plugging process may be performed using a transparent dielectric as a material. Then, a first optical member 171, for example, a first optical waveguide via pattern, may be formed on the third dielectric layer 113 using a Femto laser method. Next, first-first and second-first dielectric layers 111-1 and 112-1 may be formed on an upper surface and a lower surface of the substrate 101, respectively. For example, a stacking process or a coating process may be performed using a transparent dielectric as a material. Then, first and second optical waveguide patterns 141 and 142 may be formed on an upper surface of the first-first dielectric layer 111-1 and a lower surface of the second-first dielectric layer 112-1, respectively. The first and second optical waveguide patterns 141 and 142 may be formed, for example, by patterning a photosensitive transparent dielectric using a photolithography process. Next, first-second and second-second dielectric layers 111-2 and 112-2 covering the first and second optical waveguide patterns 141 and 142 may be formed on the upper surface of the first-first dielectric layer 111-1 and the lower surface of the second-first dielectric layer 112-1, respectively. For example, a stacking process or a coating process may be performed using a transparent dielectric as a material. Then, the first and second dielectric layers 111 and 112 may be formed.

Referring to FIG. 14, next, first to third openings h1, h2 and h3 having inclined wall surfaces may be formed in the first and second dielectric layers 111 and 112 using first and second masks M1 and M2. The first to third openings h1, h2 and h3 may be formed by laser ablation, or the like. Next, first to third mirrors 151′, 152′ and 153′ in a form of a plate with a predetermined thickness may be formed only on the inclined surfaces of each of the first to third openings h1, h2 and h3 through metal deposition, and then, a remaining space of each of the first to third openings h1, h2 and h3 may be filled with a dielectric material. If necessary, shapes of the first to third openings h1, h2 and h3 may be partially adjusted and then filled with a metal material to form a mirror having the shape illustrated in FIG. 11. Then, the first and second masks M1 and M2 may be removed. Next, third and fourth wiring patterns 123 and 124 and a third via pattern 133 may be formed on the first and second dielectric layers 111 and 112 through a via hole processing process, a plating process, and the like. Additionally, the fourth and sixth dielectric layers 114 and 116 may be formed on the first and second dielectric layers 111 and 112, respectively, through a stacking process or a coating process. Additionally, a second through-portion H2, fifth and sixth wiring patterns 125 and 126, and second and fourth via patterns 132 and 134 may be formed in the fourth and sixth dielectric layers 114 and 116 through a via hole processing process, a through-portion processing process, a plating process, and the like. Additionally, the second through-portion H2 may be filled with the fifth dielectric layer 115 through a plugging process. Additionally, the second optical member 172, for example, the second optical waveguide via pattern, may be formed in the fifth dielectric layer 115 using a Femto laser method. Additionally, the PIC 181 may be mounted using the connecting member 192, and the laser 182 may be disposed as needed. Additionally, an electrical connection metal 191 may be formed through a solder ball attachment and a reflow process. A structure of the printed circuit board 500B according to the above-described modified example embodiment may be manufactured through a series of processes.

Other descriptions may be substantially the same as those described in the printed circuit board 100A according to the above-described example embodiment, the printed circuit board 500A according to the modified example embodiment, the printed circuit board 100B according to another example embodiment, the printed circuit board 500B according to the modified example embodiment, the manufacturing example of the printed circuit board 500A according to the modified example embodiment, and therefore, redundant descriptions thereof will be omitted.

In the present disclosure, the expression ‘covering’ may include a case of covering at least a portion as well as a case of covering the whole, and may also include a case of covering not only directly but also indirectly. Furthermore, the expression ‘filling’ may include not only a case of completely filling but also a case of at least partially filling, and may also include a case of approximately filling. For example, this may include a case in which some pores or voids exist. Additionally, the expression ‘surrounding’ may include not only a case of completely surrounding but also a case of partially surrounding and a case of approximately surrounding. Additionally, the expression ‘embedding’ may include not only a case of completely embedding, but also a case of at least partially embedding.

In the present disclosure, being disposed in a through-portion may include not only a case of an object being completely disposed within the through-portion, but also the case of protruding a portion of the object upwardly or downwardly on the cross-section. For example, this may be determined in a broader meaning, such as a case of being disposed in the through-portion on a plane.

In the present disclosure, determination may be performed by including process errors, positional deviations, errors at the time of measurement, which may occur substantially in a manufacturing process. For example, being substantially vertical may include not only a case of being completely vertical, but also a case of being approximately vertical. In addition, being substantially parallel may include not only a case of being completely parallel, but also a case of being approximately parallel.

In the present disclosure, the same insulating material may denote not only a case of being the same insulating material, but also a case of including the same type of insulating material. Accordingly, the composition of the insulating material is substantially the same, but specific composition ratios thereof may be slightly different.

In the present disclosure, the meaning on the cross-section may refer to a cross-sectional shape when an object is cut vertically, or a cross-sectional shape when the object is viewed in a side-view. Furthermore, the meaning on a plane may refer to a planar shape when the object is horizontally cut, or a planar shape when the object is viewed in a top-view or a bottom-view.

In the present disclosure, for convenience, a lower side, a lower portion, and a lower surface are used to refer to a downward direction with respect to a cross-section of a drawing, and an upper side, an upper portion, and an upper surface are used to refer to an opposite direction thereof. However, this is a definition of direction for the convenience of explanation, and the scope of the claim is not specifically limited by the description of this direction, and the concept of upper/lower may be changed at any time.

In the present disclosure, a meaning of being connected is a concept including not only directly connected but also indirectly connected through an adhesive layer or the like. In addition, expressions such as first and second are used to distinguish one component from another, and do not limit the order and/or importance of the components. In some cases, a first component may be referred to as a second component without departing from the scope of rights, or similarly, the second component may be referred to as the first component.

In the present disclosure, a thickness, a width, a length, a depth, a line width, a gap, a pitch, a separation distance, surface roughness, and the like, may be measured using a scanning microscope, an optical microscope, or the like, based on a cross-section of a printed circuit board that has been polished or cut, respectively. The cut cross-section may be a vertical cross-section or a horizontal cross-section, and each value may be measured based on a required cut cross-section. For example, a width of an upper portion and/or a lower portion of a via may be measured on a cross-section that has been cut along a central axis of the via. In this case, when the value is not constant, the value may be determined as an average value of values measured at five arbitrary points.

The expression ‘example embodiment used in the present disclosure’ does not mean the same embodiment, and is provided to explain different unique characteristics. However, the example embodiments presented above do not preclude being implemented in combination with features of other example embodiments. For example, even if matters described in a particular example embodiment are not described in other example embodiments, they may be understood as explanations related to other example embodiments unless there is an explanation contrary to or contradictory to matters in other example embodiments.

The terms used in the present disclosure are used only to describe an example embodiment and are not intended to limit the present disclosure. In this case, singular expressions include plural expressions unless they are clearly meant differently in the context.

What is claimed is:

1. A printed circuit board, comprising:
a substrate having a first through-portion;
a metal pattern disposed on at least one surface of the substrate and extending onto a wall surface of the first through-portion;
a first optical member disposed in the first through-portion;
a dielectric layer disposed on the substrate, filling the first through-portion and covering each of the metal pattern and the first optical member;
an optical waveguide pattern embedded in the dielectric layer and disposed on the substrate; and
a mirror embedded in the dielectric layer and disposed on the first through-portion.

2. The printed circuit board according to claim 1,
wherein the substrate includes a glass substrate.

3. The printed circuit board according to claim 1,
wherein the metal pattern includes:
first and second wiring patterns respectively disposed on a first surface and a second surface of the substrate opposing the first surface; and
a first via pattern respectively disposed on the wall surface of the first through-portion and electrically connected to the first and second wiring patterns.

4. The printed circuit board according to claim 3,
wherein the dielectric layer includes:
first and second dielectric layers respectively disposed on the first surface and the second surface of the substrate, and covering the first and second wiring patterns, respectively, and
a third dielectric layer filling the first through-portion and covering the first optical member.

5. The printed circuit board according to claim 4,
wherein the optical waveguide pattern includes:
first and second optical waveguide patterns respectively disposed on a first side and a second side of the substrate opposing the first side and spaced apart from the substrate, and embedded in the first and second dielectric layers, respectively.

6. The printed circuit board according to claim 5,
wherein each of the first to third dielectric layers and the first and second optical waveguide patterns includes a transparent dielectric.

7. The printed circuit board according to claim 5,
wherein each of the first and second optical waveguide patterns has a refractive index higher than that of each of the first and second dielectric layers.

8. The printed circuit board according to claim 5,
wherein the mirror includes first and second mirrors respectively disposed on first side and a second side of the first through-portion opposing the first side, and respectively embedded in the first and second dielectric layers,
wherein the first mirror optically connects the first optical member and the first optical waveguide pattern to enable transmission of optical signals therethrough, and
the second mirror optically connects the first optical member and the second optical waveguide pattern to enable transmission of optical signals therethrough.

9. The printed circuit board according to claim 8,
wherein the first mirror has a surface inclined in a direction facing a first end of the first through-portion and one end of the first optical waveguide pattern, and
the second mirror has a surface inclined in a direction facing a second end of the first through-portion opposite the first end and one end of the second optical waveguide pattern.

10. The printed circuit board according to claim 8,
wherein each of the first and second mirrors include a metal.

11. The printed circuit board according to claim 8, further comprising:
a Photonic Integrated Circuit (PIC) disposed on a first side of the first dielectric layer; and
a third mirror disposed on a first side of the PIC facing the first side of the first dielectric layer, embedded in the first dielectric layer, and configured to optically connect the first optical waveguide pattern and the PIC to enable transmission of optical signals therethrough.

12. The printed circuit board according to claim 11, further comprising:
a fourth dielectric layer disposed between the first dielectric layer and the PIC, and having a second through-portion disposed between the PIC and the third mirror;
a third wiring pattern disposed between the first and fourth dielectric layers;
a second via pattern disposed on a wall surface of the second through-portion and electrically connected to the third wiring pattern;
a second optical member disposed in the second through-portion; and
a fifth dielectric layer filling the second through-portion and covering the second optical member.

13. The printed circuit board according to claim 1,
wherein the first optical member includes one or more ball lenses.

14. The printed circuit board according to claim 13,
wherein the one or more ball lenses are a plurality of ball lenses stacked in a stacking direction,
the first through-portion is tapered so that a width in cross-section of a first portion thereof is wider than a width of a second portion thereof opposing the first portion, and
among the plurality of ball lenses, a ball lens disposed on a first side in the first through-portion is wider in the cross-section than a ball lens disposed on a second side opposite the first side in the first through-portion.

15. The printed circuit board according to claim 1,
wherein the first optical member includes an optical waveguide via pattern penetrating through the dielectric layer in a stacking direction in the first through-portion.

16. The printed circuit board according to claim 15,
wherein each of the dielectric layer and the optical waveguide via pattern includes a transparent dielectric.

17. The printed circuit board according to claim 15,
wherein the optical waveguide via pattern has a refractive index higher than a refractive index of the dielectric layer.

18. A printed circuit board, comprising:
a glass substrate having a through-portion;
first and second wiring patterns respectively disposed on a first surface and a second surface opposing the first surface of the glass substrate;
a via pattern disposed on a wall surface of the through-portion and electrically connected to the first and second wiring patterns, respectively;
a dielectric layer disposed on the first surface and the second surface of the glass substrate, filling the through-portion and covering the first and second wiring patterns and the via pattern;
first and second optical waveguide patterns respectively disposed on a first side and a second side opposite the first side of the glass substrate and spaced apart from the glass substrate and respectively embedded in the dielectric layer; and
an optical member disposed in the through-portion, embedded in the dielectric layer, and optically connected to the first and second optical waveguide patterns, respectively.

19. The printed circuit board according to claim 18,
wherein the optical member includes a plurality of ball lenses stacked in a stacking direction in the through-portion, or an optical waveguide via pattern penetrating through the dielectric layer in the through-portion in the stacking direction.

20. The printed circuit board according to claim 18, further comprising:
first and second mirrors respectively disposed in a first side and a second side opposite the first side of the through-portion, respectively embedded in the dielectric layer, and configured to optically connect each of the first and second optical waveguide patterns to the optical member to enable transmission of optical signals therethrough, respectively.
